(19) United States
(12) Patent Application Publication
(10) Pub. No.: US 2006/0044500 A1
(43) Pub. Date: Mar. 2, 2006

(54) Organic thin film, method of producing the same, and field effect transistor using the same

(75) Inventors: Taira Nakagawa, Yokohama-shi (JP); Shinichi Nakamura, Isehara-shi (JP); Yasuhisa Inao, Kawasaki-shi (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, TOKYO (JP)

(21) Appl. No.: 11/212,677

(22) Filed: Aug. 29, 2005

(30) Foreign Application Priority Data
Aug. 31, 2004 (JP) 2004-253254(PAT.)

(51) Int. Cl. G02F 1/1337; H01L 29/08

(52) U.S. Cl. 349/123; 257/40

(57) ABSTRACT

A field effect transistor according to a preferable mode of the present invention employs an organic film, which is provided on an insulating layer having a plurality of insulating regions with different surface energy densities, and is aligned. Each of the plurality of insulating regions with different surface energy densities has a difference in surface energy density of preferably 10 dyne/cm or more, and a difference in height of preferably 0.5 nm or more and 100 nm or less. A compound constituting the organic film may have electrical conductivity, may be a polymer compound, and may exhibit liquid crystallinity. The preferable mode of the present invention provides a highly smooth organic film and a field effect transistor using the organic film.

### BACKGROUND OF THE INVENTION

1. Field of the Invention

The present invention relates to an organic thin film, a method of producing the same, and a field effect transistor using the same. The present invention more specifically relates to an alignment technique useful in an electronics field and to an electronic device such as a display device or IC employing the alignment technique.

2. Related Background Art

A field effect organic transistor employing an organic semiconductor can be formed on a plastic substrate or allows increase in size of a screen of a display device, unlike a silicon transistor which has difficulties in this regard. Thus, the field effect organic transistor employing an organic semiconductor is highly expected to be applied to new devices such as a flexible electronic paper and an information tag. Further, a liquid crystalline organic semiconductor may be aligned to provide a field effect organic transistor with higher performance. There is proposed in Japanese Patent Application Laid-Open No. 2003-502874 a method of producing a field effect organic transistor employing rubbing as an alignment technique.

Meanwhile, grating allows alignment of a liquid crystal material by using a shape of the grating. The grating can prevent problems caused by the rubbing such as dust, static electricity, and damages and allows alignment of the liquid crystal material. Thus, the grating is expected as a non-rubbing alignment technique. There is proposed in Japanese Patent Application Laid-Open No. H08-76077 a liquid crystal element formed by using grating.

For production of an aligned organic thin film, a method of rubbing an aligned film is often used because the method of rubbing has a large alignment control force and is generally used. However, the method of rubbing requires a cleaning step because mechanical polishing of an aligned film causes dust of a rubbing cloth to be attached to the aligned film. Further, the method of rubbing also has problems of causing static electricity and damages on the aligned film.

Production of an organic thin film aligned on an aligned film having grating formed thereon has a problem in that an alignment control force of the grating is small. Meanwhile, in a case where an amplitude of irregularities of the grating is increased for increasing an alignment control force of the grating, an amplitude of the grating may reach even several hundred nanometers. Thus, a uniform organic thin film having an amplitude equal to or less than the amplitude of the grating is hardly produced on the grating. In a case where the above-described methods are used, an interface between the aligned film and the organic thin film is hardly used.

### SUMMARY OF THE INVENTION

The present invention has been made in view of the background art, and an object of the present invention is to provide a highly smooth organic film and a method of producing the same without requiring mechanical polishing such as rubbing and without using alignment control by a shape having deep irregularities such as grating.

Another object of the present invention is to provide a field effect transistor without damages, dust, or the like caused and with reduced variation in properties by using the above-described organic film for a channel part of the field effect transistor.

That is, a first aspect of the present invention relates to an organic film, which is provided on an insulating layer having a plurality of insulating regions with different surface energy densities, and is aligned.

A second aspect of the present invention relates to a method of producing the above-described organic film, including forming a plurality of insulating regions with different surface energy densities by using an electron beam or near field light.

A third aspect of the present invention relates to a field effect transistor including the above-described organic film for a channel part of the field effect transistor.

Each of the plurality of insulating regions with different surface energy densities is preferably structured.

A difference between a surface energy density of an insulating region of the plurality of insulating regions with different surface energy densities and a surface energy density of another insulating region adjacent to the insulating region is preferably 10 dyne/cm or more.

Each of the plurality of insulating regions with different surface energy densities is preferably structured with a period of 1 μm or less.

Each of the plurality of insulating regions with different surface energy densities is preferably structured with a period of a 0.5 times or more and 100 times or less molecular length of a compound constituting the organic film.

A difference in height between an insulating region of the plurality of insulating regions with different surface energy densities and another insulating region adjacent to the insulating region is preferably 0.5 nm or more and 100 nm or less.

The compound constituting the organic film preferably has electrical conductivity.

The compound constituting the organic film is preferably a polymer compound.

The compound constituting the organic film preferably exhibits liquid crystallinity.

Note that, the term “structured” in the present invention refers to a state where regions with different surface energy densities exist periodically.

### BRIEF DESCRIPTION OF THE DRAWINGS

In the accompanying drawings:

FIGS. 1A, 1B, 1C, 1D, 1E, 1F, and 1G are explanatory drawings collectively showing an example of a production process for an organic thin film according to the present invention;

FIGS. 2A, 2B, 2C, 2D, and 2E are explanatory drawings collectively showing another example of a production process for an organic thin film used in examples of the present invention;

FIGS. 3A, 3B, 3C, 3D, 3E, and 3F are explanatory drawings collectively showing still another example of a production process for an organic thin film used in examples of the present invention;

FIGS. 4A, 4B, 4C, 4D, and 4E are explanatory drawings collectively showing yet another example of a production process for an organic thin film used in examples of the present invention;

FIGS. 5A, 5B, 5C, 5D, 5E, and 5F are explanatory drawings collectively showing an example of a production process for a field effect transistor used in examples of the present invention;

FIG. 6 is an atomic force microscope photograph of a thin film having formed thereon a pattern of octadecyltrichlorosilane used in Example 1 of the present invention; and

FIG. 7 is an atomic force microscope photograph of a thin film having formed thereon a pattern of octadecyltrichlorosilane used in Example 2 of the present invention.

### DESCRIPTION OF THE PREFERRED EMBODIMENTS

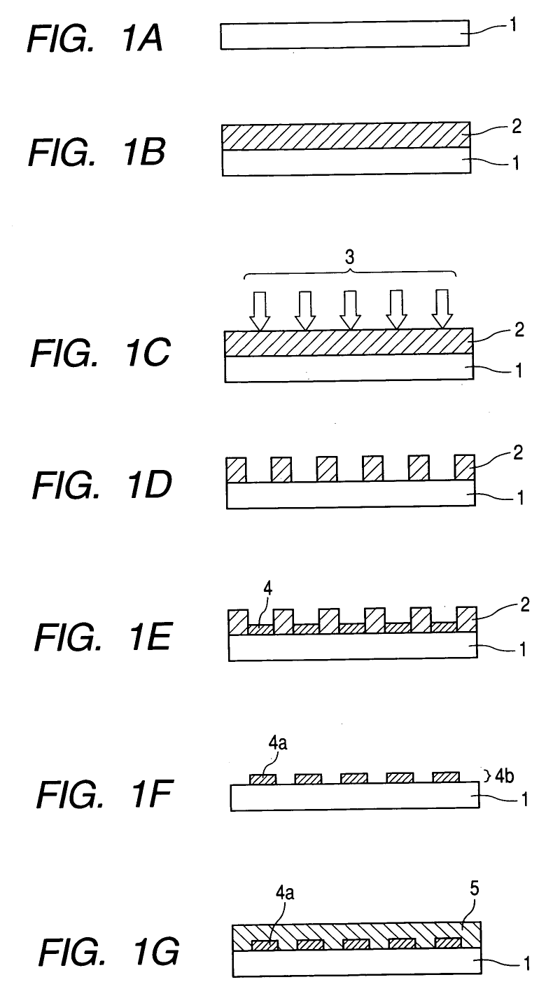

Hereinafter, a best mode of the present invention will be described by using FIGS. 1A to 1G.

A process schematically shown in FIGS. 1A to 1G is an example of a method of producing an organic thin film according to the present invention, and an organic thin film produced through the process schematically shown in FIGS. 1A to 1G is an example of an organic thin film of the present invention.

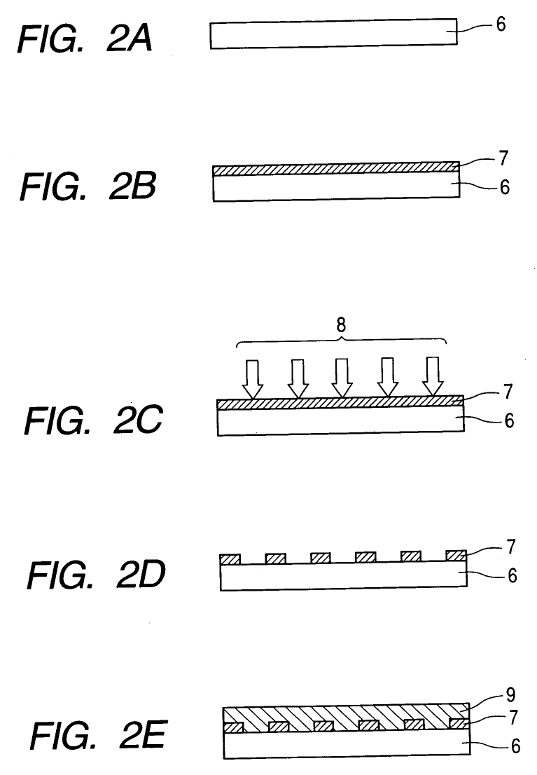

Description is given of the process schematically shown in FIGS. 1A to 1G. First, an electron beam resist 2 is formed on a first insulating substrate 1 (FIG. 1B). Next, the electron beam resist 2 is irradiated with an electron beam 3 to be patterned (FIG. 1D). Then, a film composed of an insulating surface treatment agent 4 with a different surface energy density from that of the substrate is formed on a part of the electron beam resist 2 patterned by the electron beam 3 (FIG. 1E). Then, the electron beam resist 2 is peeled off to form an insulating layer 4b having an insulating surface treated film 4a with a different surface energy density (FIG. 1F) Note that, a surface part of the substrate 1 and the surface treated film 4a are collectively referred to as the insulating layer 4b. Next, an organic thin film 5 is formed on the insulating layer 4b having the insulating surface treated film 4a with a different surface energy density. As in a process schematically shown in FIGS. 2A to 2E, the process may employ an method involving: forming an insulating region with a different surface energy density from that of the substrate on the substrate by using a coupling agent 7 or the like; and directly patterning the insulating region by an electron beam 8.

The substrate used in the present invention is not particularly limited. Examples of a substrate with a typical shape include a sheet substrate and a film substrate, but the substrate may have other shapes. Examples of a material for the substrate that can be used include an inorganic material, an organic material, and a hybrid material of organic and inorganic materials. Examples of the inorganic material include silicon, glass, and quartz. The organic material is preferably a polymer material. Examples of the polymer material include an acrylic polymer, a vinyl-based polymer, an ester-based polymer, an imide-based polymer, a urethane-based polymer, a diazo-based polymer, and a cinnamoyl-based polymer. Specific examples of the polymer material include polyvinylidene fluoride, polyethylene terephthalate, and polyethylene. Two or more layers of films, sheets, or the like formed of the above-described materials may be laminated and used. A substrate of a laminate structure has an effect of enhancing a dielectric voltage. As smoothness of a substrate surface, the substrate desirably has a surface roughness of 10 nm or less. Further, a preferably selected substrate material is a material forming an organic semiconductor layer with a favorable ordered structure on a substrate.

A difference of the respective regions in surface energy density of insulating regions with different surface energy densities of the present invention is preferably 10 dyne/cm or more.

Examples of a material constituting the regions with different surface energy densities used in the present invention include a silane coupling agent, a titanate-based coupling agent, and photosensitive polyimide, but the material is not limited thereto. However, a silane coupling agent is preferable from a viewpoint of ease in retaining smoothness of the substrate. Examples of the silane coupling agent include hexamethyldisilazane (HMDS), alkyl trichlorosilane, alkyl trimethoxysilane, alkyl triethoxysilane, perfluoroalkyl ethyl trichlorosilane, aminoalkyl trichlorosilane, hydroxyalkyl trichlorosilane, and phenylalkyl trichlorosilane.

A shape of each of the insulating regions with different surface energy densities of the present invention is not particularly limited. Examples of the shape of each of the regions include a wavy shape, a broken line shape, a linear shape, a concentric shape, an elliptical shape, other circular shapes, a triangular shape, a tetragonal shape, and other polygonal shapes. Two or more types of shapes may be used in combination, to thereby provide different alignment states in the same substrate.

A sectional structure of each of the insulating regions with different surface energy densities of the present invention is not particularly limited. Examples of a sectional shape of each of the insulating regions with different surface energy densities include a smooth shape, a circular shape, an elliptical shape, other circular shapes, a trapezoidal shape, a triangular shape, and other polygonal shapes. If the section of each of the insulating regions is not smooth, a difference in height between the regions with different surface energy densities is preferably 100 nm or less. Too large a difference in height may cause problems similar to those involved in grating. A lower limit of the difference in height is not particularly defined. However, in a case where a film is formed to change the surface energy density, the difference in height is preferably 0.5 nm or more from a viewpoint of obtaining an effective film thickness. A length of a structure of each of the insulating regions with different surface energy densities of the present invention is not particularly limited, but is preferably 5 μm or less.

A period of the respective insulating regions with different surface energy densities of the present invention is not particularly limited, but is preferably 1 μm or less. In another way of defining the period, the insulating regions with different surface energy densities are preferably structured with a period of a 0.5 times or more and 100 times or less molecular length of a compound constituting the organic thin film.

A size of the organic thin film used in the present invention is not particularly limited as long as the organic thin film covers the insulating regions with different surface energy densities. A preferable film thickness is 10 μm or less and 0.5 nm or more, and a more preferable film thickness is 1 μm or less and 5 nm or more. Smoothness of the organic thin film used in the present invention is not particularly limited, but the organic thin film has a surface roughness of preferably 10 nm or less.

The compound constituting the organic thin film used in the present invention is not particularly limited. A polymer compound is preferable from a viewpoint of generally easy formation by application. However, the compound is not limited to the polymer compound, and preferable examples thereof include compounds listed below.

(1) A conjugated polymer compound such as a polyacetylene derivative, a polythiophene derivative having a thiophene ring, a poly(3-alkylthiophene) derivative, a poly(3,4-ethylenedioxythiophene) derivative, a polythienylenevinylene derivative, a polyphenylene derivative having a benzene ring, a polyphenylenevinylene derivative, a polypyridine derivative containing a nitrogen atom, a polypyrrole derivative, a polyaniline derivative, or a polyquinoline derivative; and an oligomer represented by dimethyl sexithiophene or quarterthiophene.

(2) A stacking organic molecule (easily stacked organic molecule) represented by: acenes such as perylene, tetracene, and pentacene; phthalocyanines such as a copper phthalocyanine derivative; and porphyrins such as a copper porphyrin derivative.

(3) A discotic liquid crystal represented by a triphenylene derivative; and a smectic liquid crystal represented by a phenyl naphthalene derivative or a benzothiazole derivative.

(4) A liquid crystal polymer represented by a poly(9,9-dialkylfluorene-bithiophene) copolymer.

Further, the compound constituting the organic thin film is preferably a compound having a π conjugate system such as a conjugate polymer compound, and a polythiophene derivative is particularly preferable. However, the compound having a π conjugate system is not limited to the polythiophene derivative, and examples thereof include compounds each having a structure shown below. 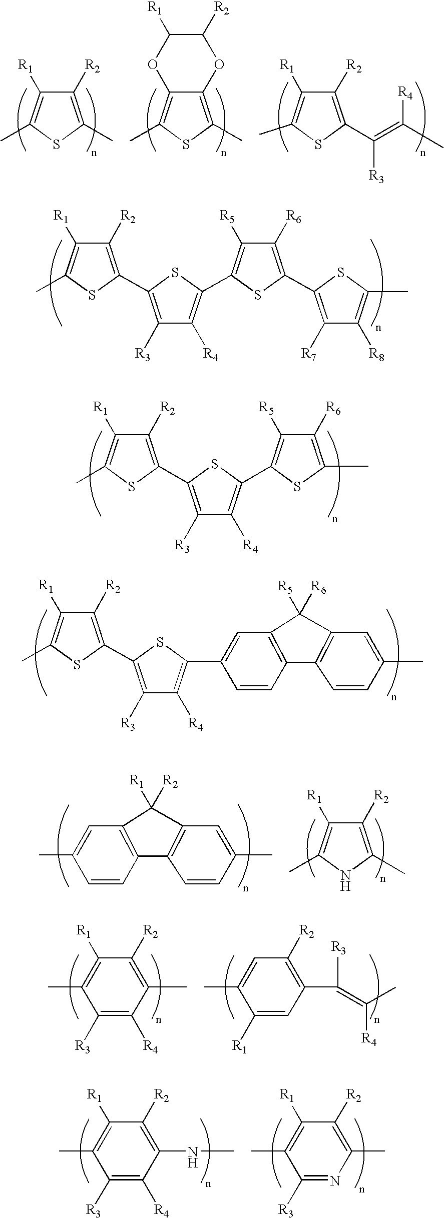
(In the formulae, R₁, R₂, R₃, R₄, R₅, and R₆ each represent H, F, or a linear, branched, or cyclic alkyl group, alkoxy group, or perfluoroalkyl group having 1 to 20 carbon atoms. n represents a positive integer.)

A molecular weight of the conjugated polymer compound is not particularly limited, but the conjugated polymer compound preferably has a weight average molecular weight of 5,000 to 100,000 in view of solubility to a solvent, ease of film formation, and the like.

The compound constituting the organic thin film used in the present invention is preferably a liquid crystal material.

A method of forming a pattern used in the present invention is not particularly limited, but examples thereof that can be used include: a method using an electron beam; a method using near field light; a method using ultraviolet light; a method using a scanning probe microscope or the like; and a contact printing method. Those methods may be combined to form a plurality of hydrophilic regions or hydrophobic regions with different surface energy densities. The method of forming a pattern is preferably a method which allows structurization of regions patterned with a period shorter than a molecular length of the compound constituting the organic thin film.

A method of forming an organic thin film used in the present invention is not particularly limited. However, examples thereof by using an organic material include electrolytic polymerization, casting, spin coating, immersion coating, screen printing, micromolding, microcontacting, roll coating, spray coating, and an LB method. Examples of an effective method of forming an organic thin film include vacuum evaporation, a CVD method, electron beam evaporation, resistance heating evaporation, and sputtering depending on a material to be used. The organic thin film may be patterned into a desired shape by photolithography and etching treatment. Other examples of an effective patterning method include soft lithography and an inkjet method.

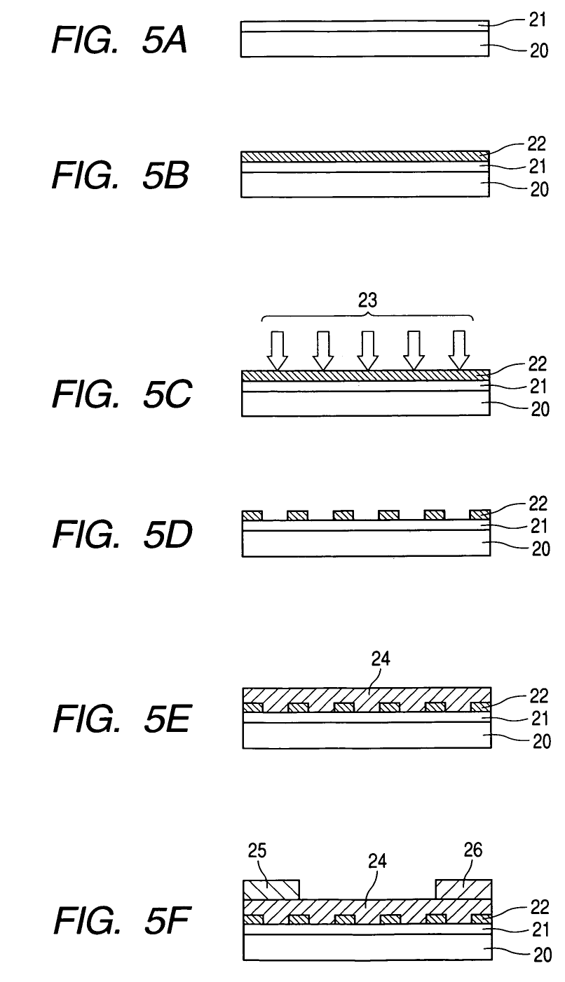

As shown in FIG. 5F, an example of a field effect transistor of the present invention includes: at least part of a gate insulating layer on an organic semiconductor layer side as an insulating layer having a plurality of insulating regions with different surface energy densities; and an organic thin film 24 of the present invention thereon as an organic semiconductor layer. An entire gate insulating layer may be composed of an insulating layer having a plurality of insulating regions with different surface energy densities.

Meanwhile, the gate electrode needs not serve also as a substrate as shown in FIGS. 5A to 5F. An example thereof is a gate electrode formed of a metal or the like provided on a glass substrate, a plastic substrate, a silicon substrate, or the like.

Positions of a source electrode and a drain electrode are not limited to those shown in the figures. The source electrode and the drain electrode may be provided on a gate insulating layer side of the organic thin film.

The configuration of the field effect transistor is not limited to that described above, and may be arbitrarily modified without departing from the scope of the present invention.

Hereinafter, the present invention will be described in more detail by way of examples. However, the present invention is not limited to the examples.

### EXAMPLE 1

FIGS. 1A to 1G collectively show a production process for an organic thin film of Example 1.

An electron beam resist 2 was formed on a glass substrate 1 by spin coating. Next, the electron beam resist 2 was irradiated with an electron beam 3, to thereby form a resist pattern with a width of 370 nm and a pitch of 650 nm.

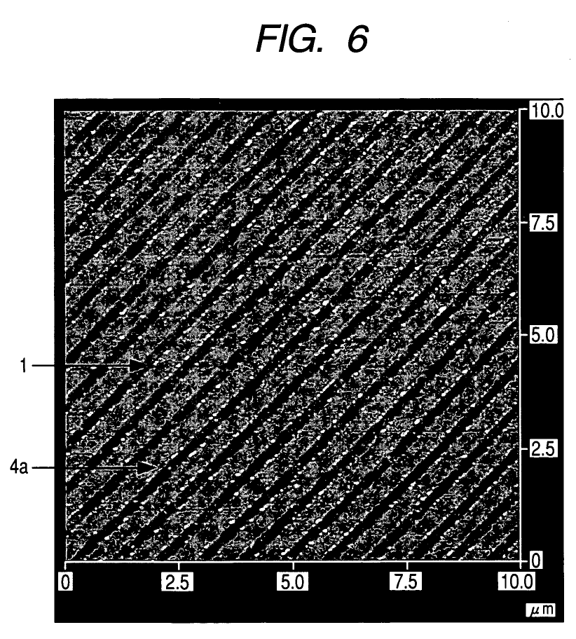

Then, the glass substrate 1 having formed thereon the electron beam resist 2 with a pitch of 650 nm was immersed in a hexadecane solution (0.06 mol/l) of octadecyltrichlorosilane for 1 hour, and was taken out. The glass substrate 1 taken out was subjected to ultrasonic cleaning in hexadecane for 2 minutes, and then subjected to ultrasonic cleaning twice in chloroform for 2 minutes each. In this way, the electron beam resist 2 was peeled off, and a pattern of octadecyltrichlorosilane as an insulating region 4a with a different surface energy density from that of the glass substrate 1 was formed on the glass substrate 1. The surface treated region 4a was hydrophobic, indicating that octadecyltrichlorosilane treatment was assuredly performed. Further, surface observation of the resulting substrate by an atomic force microscope confirmed that the substrate surface had a difference in height (part represented by the insulating layer 4b in FIG. 1F) of about 2 nm and a pitch of 650 nm. FIG. 6 shows the result of observation of the surface treated region by an atomic force microscope. A length of octadecyltrichlorosilane is about 2 nm, and thus a convex region (part 4a in FIG. 6) represents octadecyltrichlorosilane and a concave region (part 1 in FIG. 6) represents the glass substrate.

A surface energy density of the glass substrate alone was measured, resulting in 72.5 dyne/cm. A surface energy density of the glass substrate uniformly subjected to octadecyltrichlorsilane treatment was measured, resulting in 25.6 dyne/cm. Thus, a difference in surface energy density between the region subjected to the octadecyltrichlorosilane treatment and the region of the glass substrate was 45 dyne/cm or more.

Next, a chlorobenzene solution (0.01 g/ml) of a polymer compound exhibiting liquid crystallinity poly(9,9-dioctylfluorene-co-bithiophene) was applied onto the glass substrate 1 on a side having formed thereon the pattern of octadecyltrichlorosilane by spin coating, to thereby form an organic thin film 5 (thickness of 50 nm) on an entire surface of the glass substrate 1. Then, the glass substrate 1 (shown in FIG. 1G) having the organic thin film 5 formed on its surface was dried in a nitrogen atmosphere at 280° C. for 1 hour.

The observation of the dried organic thin film 5 on the surface of the glass substrate 1 by a polarization microscope confirmed that uniform monodomain alignment was obtained.

### EXAMPLE 2

FIGS. 1A to 1G collectively show a production process for an organic thin film of Example 2.

An electron beam resist 2 was formed on a glass substrate 1 by spin coating. Next, the electron beam resist 2 was irradiated with an electron beam 3, to thereby form a resist pattern with a pitch of 80 nm.

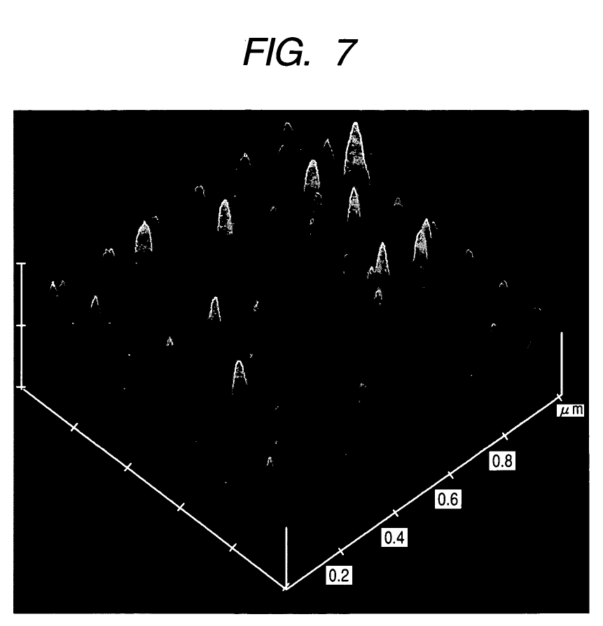

Then, the glass substrate 1 having formed thereon the electron beam resist 2 with a pitch of 80 nm was immersed in a hexadecane solution (0.06 mol/l) of tridecafluoro-tetrahydrooctyl-trichlorosilane for 1 hour, and was taken out. The glass substrate 1 taken out was subjected to ultrasonic cleaning in hexadecane for 2 minutes, subjected to ultrasonic cleaning twice in chloroform for 2 minutes each, and subjected to ultrasonic cleaning twice in perfluoroacetic acid for 5 minutes each. In this way, the electron beam resist 2 was peeled off, and a pattern of tridecafluoro-tetrahydrooctyl-trichlorosilane as an insulating region 4a with a different surface energy density from that of the glass substrate 1 was formed on the glass substrate 1. FIG. 7 shows the result of observation of the surface treated region by an atomic force microscope.

A surface energy density of the glass substrate uniformly subjected to tridecafluoro-tetrahydrooctyl-trichlorsilane treatment was measured, resulting in 15.8 dyne/cm. Thus, a difference in surface energy density between the region subjected to the tridecafluoto-tetrahydrooctyl-trichlorosilane treatment and the region of the glass substrate was 50 dyne/cm or more.

Next, a chlorobenzene solution (0.01 g/ml) of a polymer compound exhibiting liquid crystallinity poly(9,9-dioctylfluorene-co-bithiophene) was applied onto the glass substrate 1 on a side having formed thereon the pattern of tridecafluoro-tetrahydrooctyl-trichlorosilane 4 by spin coating, to thereby form an organic thin film 5 on the entire surface of the glass substrate 1. Then, the glass substrate 1 (shown in FIG. 1G) having the organic thin film 5 formed on its surface was dried in a nitrogen atmosphere at 280° C. for 1 hour.

The observation of the dried organic thin film 5 on the surface of the glass substrate 1 by a polarization microscope confirmed that uniform monodomain alignment was obtained.

### EXAMPLE 3

FIGS. 2A to 2E collectively show a production process for an organic thin film of Example 3.

A silicon substrate 6 was immersed in a chloroform solution (0.06 mol/l) of octadecyltrichlorosilane for 1 hours, and was taken out. The silicon substrate 6 taken out was subjected to ultrasonic cleaning twice in chloroform for 2 minutes each, to thereby form uniformly a coupling agent octadecyltrichlorosilane 7 on the silicon substrate 6.

Then, octadecyltrichlorosilane 7 formed was irradiated with an electron beam 8, to thereby form a pattern including octadecyltrichlorosilane 7 with a pitch of 650 nm and the surface of the silicon substrate 6 on the silicon substrate 6.

A surface energy density of the silicon substrate alone was measured, resulting in 74.4 dyne/cm. A surface energy density of the silicon substrate uniformly subjected to octadecyltrichlorosilane treatment was measured, resulting in 23.5 dyne/cm. Thus, a difference in surface energy density between the region subjected to the octadecyltrichlorosilane treatment and the region of the silicon substrate was 50 dyne/cm or more.

Next, a xylene solution (0.01 g/ml) of a polymer compound exhibiting liquid crystallinity poly(9,9-dioctylfluorene-co-bithiophene) was applied onto the silicon substrate 6 on a side having formed thereon the pattern of octadecyltrichlorosilane 7 by casting, to thereby form an organic thin film 9 on the entire surface of the silicon substrate 6. Then, the silicon substrate 6 (shown in FIG. 2E) having the organic thin film 9 formed on its surface was dried under vacuum at 280° C. for 1 hour.

The observation of the dried organic thin film 9 on the surface of the silicon substrate 6 by a polarization microscope confirmed that uniform monodomain alignment was obtained.

### EXAMPLE 4

FIGS. 2A to 2E collectively show a production process for an organic thin film of Example 4.

A silicon substrate 6 was immersed in a chloroform solution (0.06 mol/l) of aminopropyltriethoxysilane for 1 hour, and was taken out. The silicon substrate 6 taken out was subjected to ultrasonic cleaning twice in chloroform for 2 minutes each, to thereby form uniformly a coupling agent aminopropyltriethoxysilane 7 on the silicon substrate 6.

Then, aminopropyltriethoxysilane 7 formed was irradiated with an electron beam 8, to thereby form a pattern including aminopropyltriethoxysilane 7 with a pitch of 80 nm and the surface of the silicon substrate 6 on the silicon substrate 6.

A surface energy density of the silicon substrate uniformly subjected to aminopropyltriethoxysilane treatment was measured, resulting in 62.2 dyne/cm. Thus, a difference in surface energy density between the region subjected to the aminopropyltriethoxysilane treatment and the region of the silicon substrate was 10 dyne/cm or more.

Next, a xylene solution (0.01 g/ml) of a polymer compound exhibiting liquid crystallinity poly(9,9-dioctylfluorene-co-bithiophene) was applied onto the silicon substrate 6 on a side having formed thereon the pattern of aminopropyltriethoxysilane 7 by casting, to thereby form an organic thin film 9 on the entire surface of the silicon substrate 6. Then, the silicon substrate 6 (shown in FIG. 2E) having the organic thin film 9 formed on its surface was dried under vacuum at 280° C. for 1 hour.

The observation of the dried organic thin film 9 on the surface of the silicon substrate 6 by a polarization microscope confirmed that uniform monodomain alignment was obtained.

### EXAMPLE 5

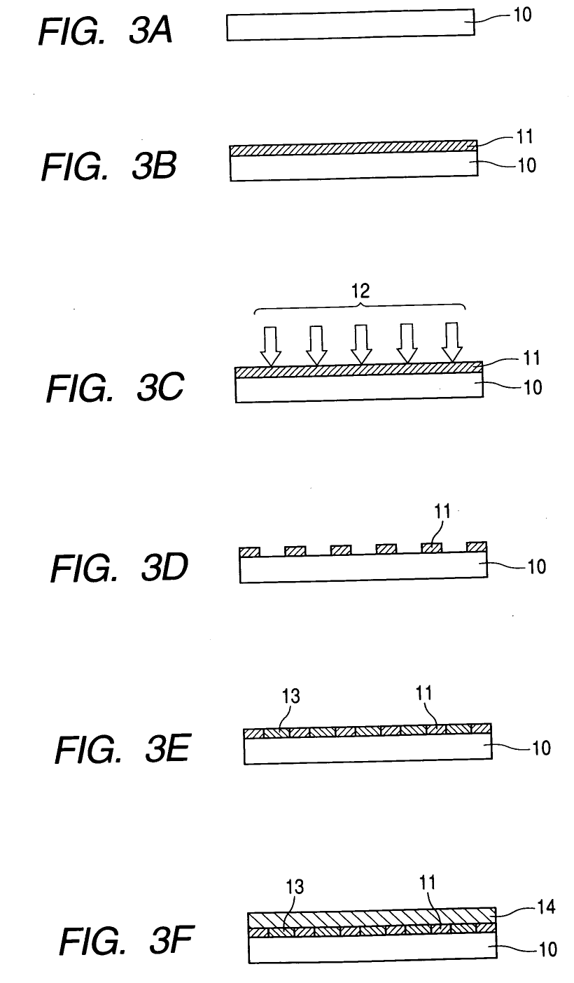

FIGS. 3A to 3F collectively show a production process for an organic thin film of Example 5.

Hexamethyldisilazane was applied onto a silicon substrate 10 by spin coating, and the whole was dried at 200° C. for 10 minutes, to thereby form uniformly a coupling agent hexamethyldisilazane 11 on the silicon substrate 10. Next, hexamethyldisilazane 11 formed was irradiated with an electron beam 12, to thereby form a pattern of hexamethyldisilazane 11 with a pitch of 80 nm on the silicon substrate 10.

The silicon substrate 10 having formed thereon the pattern of hexamethyldisilazane 11 was immersed in a chloroform solution (0.06 mol/l) of 1.5 aminopropyltriethoxysilane for 1 hour, and was taken out. The silicon substrate 10 taken out was subjected to ultrasonic cleaning twice in chloroform for 2 minutes each, to thereby form a pattern of both a coupling agent hexamethyldisilazane 11 and a coupling agent aminopropyltriethoxysilane 13 on the silicon substrate 10.

A surface energy density of the silicon substrate uniformly subjected to aminopropyltriethoxysilane treatment was measured, resulting in 62.2 dyne/cm. A surface energy density of the silicon substrate uniformly subjected to hexamethyldisilazane treatment was measured, resulting in 43.8 dyne/cm. Thus, a difference in surface energy density between the region subjected to the aminopropyltriethoxysilane treatment and the region subjected to the hexamethyldisilazane treatment was 15 dyne/cm or more.

Next, a tetrahydrofuran solution (0.01 g/ml) of a polymer compound exhibiting liquid crystallinity poly(9,9-dioctylfluorene-co-bithiophene) was applied onto the silicon substrate 10 on a side having formed thereon the pattern of hexamethyldisilazane 11 and aminopropyltriethoxysilane 13 by casting, to thereby form an organic thin film 14 on the entire surface of the silicon substrate 10. Then, the silicon substrate 10 (shown in FIG. 3F) having the organic thin film 14 formed on its surface was dried in a nitrogen atmosphere at 280° C. for 1 hour.

The observation of the dried organic thin film 14 on the surface of the silicon substrate 10 by a polarization microscope confirmed contrasts.

Further, the observation of the dried organic thin film 14 on the surface of the silicon substrate 10 by a polarization microscope confirmed that uniform monodomain alignment was obtained.

### EXAMPLE 6

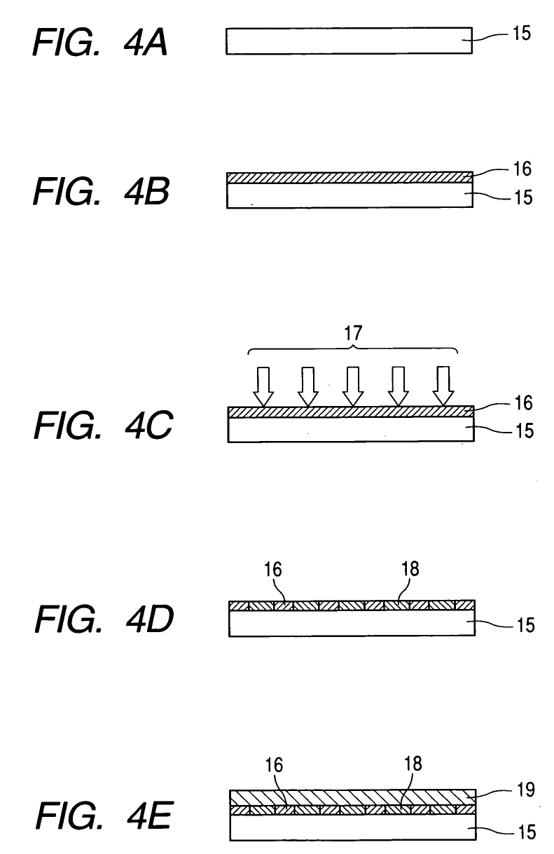

FIGS. 4A to 4E collectively show a production process for an organic thin film of Example 6.

Alkali development positive-type photosensitive polyimide was spin coated on a polyimide substrate 15, and the whole was dried at 85° C. for 2 minutes and at 100° C. for 2 minutes, to thereby form uniformly a photosensitive polyimide layer 16. Then, a near field exposure device was used to irradiate the photosensitive polyimide layer 16 with near field light 17 through an exposure mask with a pitch of 200 nm. At this time, photosensitive polyimide 18 of exposed part had a higher surface energy density than that of photosensitive polyimide 16 of non-exposed part, indicating that regions with different surface energy densities coexist on the polyimide substrate 15.

A chlorobenzene solution (0.01 g/ml) of a polymer compound exhibiting liquid crystallinity poly(9,9-dodecylfluorene-co-bithiophene) was applied onto the polyimide substrate 15 on a side having formed thereon the pattern of photosensitive polyimide as the regions 16 and 18 with different surface energy densities by an inkjet method, to thereby form an organic thin film 19. Then, the polyimide substrate 15 (shown in FIG. 4E) having the organic thin film 19 formed on its surface was dried in a nitrogen atmosphere at 280° C. for 1 hour.

The observation of the dried organic thin film 19 on the polyimide substrate 15 by a polarization microscope confirmed contrasts.

Further, the observation of the dried organic thin film 19 on the polyimide substrate 15 by a polarization microscope confirmed that uniform monodomain alignment was obtained.

### EXAMPLE 7

FIGS. 2A to 2E collectively show a production process for an organic thin film of Example 7.

A glass substrate 6 was immersed in a chloroform solution (0.06 mol/l) of octadecyltrichlorosilane for 1 hour, and was taken out. The glass substrate 6 taken out was subjected to ultrasonic cleaning twice in chloroform for 2 minutes each, to thereby form uniformly a coupling agent octadecyltrichlorosilane 7 on the glass substrate 6.

Then, octadecyltrichlorosilane 7 formed by using a metal mask was irradiated with ultraviolet light 8, to thereby form a pattern including octadecyltrichlorosilane 7 with a pitch of 1,500 nm and the surface of the glass substrate 6 on the glass substrate 6.

Next, a xylene solution (0.01 g/ml) of a polymer compound exhibiting liquid crystallinity poly(9,9-dioctylfluorene-co-bithiophene) was applied onto the glass substrate 6 on a side having formed thereon the pattern of octadecyltrichlorosilane 7 by spin coating, to thereby form an organic thin film 9 on the entire surface of the glass substrate 6. Then, the glass substrate 6 (shown in FIG. 2E) having the organic thin film 9 formed on its surface was dried in atmospheric air at 280° C. for 1 hour.

The observation of the dried organic thin film 9 on the surface of the glass substrate 6 by a polarization microscope confirmed contrasts.

Further, the observation of the dried organic thin film 9 on the surface of the glass substrate 6 by a polarization microscope confirmed that uniform monodomain alignment was obtained.

### EXAMPLE 8

FIGS. 1A to 1G collectively show a production process for an organic thin film of Example 8.

An electron beam resist 2 was formed on a silicon substrate 1 by spin coating. Next, the electron beam resist 2 was irradiated with an electron beam 3, to thereby form a resist pattern with a pitch of 80 nm.

Then, the silicon substrate 1 having formed thereon the electron beam resist 2 with a pitch of 80 nm was immersed in a hexadecane solution (0.06 mol/l) of octadecyltrichlorosilane for 1 hour, and was taken out. The silicon substrate 1 taken out was subjected to ultrasonic cleaning in hexadecane for 2 minutes, and then subjected to ultrasonic cleaning twice in chloroform for 2 minutes each. In this way, the electron beam resist 2 was peeled off, and a pattern of octadecyltrichlorosilane as an insulating region 4a with a different surface energy density from that of the silicon substrate 1 was formed on the silicon substrate 1.

Next, a low molecular weight compound (trade name: KN5027; available from Chisso Corporation) exhibiting liquid crystallinity was applied onto the silicon substrate 1 on a side having formed thereon the pattern of octadecyltrichlorosilane by using a dropping pipette. An organic thin film 5 was formed on the silicon substrate 1, and the whole was dried.

The observation of the dried organic thin film 5 on the surface of the silicon substrate 1 by a polarization microscope confirmed that uniform monodomain alignment was obtained.

### EXAMPLE 9

FIGS. 5A to 5F collectively show a production process for a transistor of Example 9.

A thermally-oxidized film (thickness' of 100 nm) of silicon as a gate insulating layer 21 was formed on the surface of a silicon substrate 20 highly doped into n-type to be used as a substrate and a gate electrode (FIG. 5A).

Next, the silicon substrate 20 (used as the substrate and the gate electrode) having formed thereon the gate insulating layer 21 was immersed in a chloroform solution (0.06 mol/l) of tridecafluoro-tetrahydrooctyl-trichlorosilane for 1 hour, and was taken out. The silicon substrate 20 taken out was subjected to ultrasonic cleaning twice in chloroform for 2 minutes each. In this way, a coupling agent tridecafluoro-tetrahydrooctyl-trichlorosilane 22 was uniformly formed on the gate insulating layer 21 of the silicon substrate 20 (FIG. 5B).

Next, tridecafluoro-tetrahydrooctyl-trichlorosilane 22 formed was irradiated with an electron beam 23, to thereby form a pattern including tridecafluoro-tetrahydrooctyl-trichlorosilane 22 with a pitch of 80 nm and the surface of the gate insulating layer 21 on the gate insulating layer 21 (FIG. 5D).

Next, a chlorobenzene solution (0.01 g/ml) of a polymer compound poly(3-hexylthiophene) was applied onto the silicon substrate 20 on a side having formed thereon the pattern of tridecafluoro-tetrahydrooctyl-trichlorosilane 22 by an inkjet method, to thereby form an organic thin film 24 on the silicon substrate 20 having formed thereon the pattern of tridecafluoro-tetrahydrooctyl-trichlorosilane 22. Then, the silicon substrate 20 (shown in FIG. 5E) having the organic thin film 24 formed on its surface was dried under vacuum at 200° C. for 1 hour.

Next, gold (100 nm) was deposited on the organic thin film 24 by using a mask, to thereby form a source electrode 25 and a drain electrode 26. A gold wire of 0.1 mmΦ was wired to each of the gate electrode 20, the drain electrode 26, and the source electrode 25 by using a silver paste, to thereby produce a field effect organic transistor element (FIG. 5F).

Next, a drain current of the obtained field effect organic transistor element was measured at a gate voltage of 0 V to −20 V and a voltage between the source electrode and the drain electrode of 0 V to −20 V. The results of the measurement provided a favorable saturation curve.

### EXAMPLE 10

FIGS. 5A to 5F collectively show a production process for a transistor of Example 10.

A thermally-oxidized film (thickness of 100 nm) of silicon as a gate insulating layer 21 was formed on the surface of a silicon substrate 20 highly doped into n-type to be used as a substrate and a gate electrode (FIG. 5A).

Next, the silicon substrate 20 having formed thereon the gate insulating layer 21 was immersed in a chloroform solution (0.06 mol/l) of octadecyltrichlorosilane for 1 hour, and was taken out. The silicon substrate 20 taken out was subjected to ultrasonic cleaning twice in chloroform for 2 minutes each. In this way, octadecyltrichlorosilane 22 was uniformly formed on the gate insulating layer 21 of the silicon substrate 20 (FIG. 5B).

Next, octadecyltrichlorosilane 22 formed was irradiated with an electron beam 23, to thereby form a pattern including octadecyltrichlorosilane 22 with a pitch of 80 nm and the surface of the gate insulating layer 21 on the gate insulating layer 21 (FIG. 5D).

Next, a chlorobenzene solution (0.01 g/ml) of a polymer compound exhibiting liquid crystallinity poly(9,9-dodecylfluorene-co-bithiophene) was applied onto the silicon substrate 20 on a side having formed thereon the pattern of octadecyltrichlorosilane 22 by an inkjet method, to thereby form an organic thin film 24 on the silicon substrate 20 having formed thereon the pattern of octadecyltrichlorosilane 22. Then, the silicon substrate 20 (shown in FIG. 5E) having the organic thin film 24 formed on its surface was dried under vacuum at 200° C. for 1 hour.

Next, gold (100 nm) was deposited on the organic thin film 24 by using a mask, to thereby form a source electrode 25 and a drain electrode 26. A gold wire of 0.1 mmΦ was wired to each of the gate electrode 20, the drain electrode 26, and the source electrode 25 by using a silver paste, to thereby produce a field effect organic transistor element (FIG. 5F).

### COMPARATIVE EXAMPLE 1

A thermally-oxidized film (thickness of 100 nm) of silicon as a gate insulating layer was formed on the surface of a silicon substrate highly doped into n-type to be used as a substrate and a gate electrode. Polyimide was spin coated onto the gate insulating layer, and the whole was dried at 80° C. for 15 minutes and at 180° C. for 60-minutes.

Next, the surface of polyimide was subjected to rubbing twice at an indentation of 0.7 mm, a rotation speed of 1,000 rpm, and a rubbing speed of 50 mm/s. After the rubbing, the resultant was subjected to ultrasonic cleaning twice in isopropanol for 2 minutes each, and the silicon substrate provided with polyimide was dried at 100° C. for 10 minutes. Then, a chlorobenzene solution (0.01 g/ml) of a polymer compound exhibiting liquid crystallinity poly(9,9-dodecylfluorene-co-bithiophene) was applied onto polyimide subjected to rubbing by an inkjet method, to thereby form an organic thin film. Then, the silicon substrate having formed thereon the organic thin film was dried under vacuum at 200° C. for 1 hour.

Next, gold (100 nm) was deposited on the organic thin film by using a mask, to thereby form a source electrode and a drain electrode. A gold wire of 0.1 mmΦ was wired to each of the gate electrode, the drain electrode, and the source electrode by using a silver paste, to thereby produce a field effect organic transistor element.

Next, drain currents of the field effect organic transistor elements obtained in Example 10 and Comparative Example 1 were measured at a gate voltage of 0 V to −20 V and a voltage between the source electrode and the drain electrode of 0 V to −20 V. The transistor element produced in Example 10 had a drain current of 1 order higher than that of the transistor element produced in Comparative Example 1. The results indicate that the field effect organic transistor element of Example 10 of the present invention had a favorable channel formed.

The present invention requires no mechanical polishing such as rubbing for alignment, and thus allows alignment of an organic thin film without causing dust or damages. Further, the present invention employs no alignment control by a shape having deep irregularities such as grating, and thus allows production of a highly smooth organic thin film.

The field effect transistor employing the organic thin film of the present invention for a channel part thereof requires no mechanical polishing for alignment. Therefore, the present invention can provide a field effect transistor without damages, dust, or the like caused and with reduced variation in properties.

This application claims priority from Japanese Patent Application No. 2004-253254 filed Aug. 31, 2004, which is hereby incorporated by reference herein.

What is claimed is:

1. An organic film, which is provided on an insulating layer having a plurality of insulating regions with different surface energy densities, and is aligned.

2. The organic film according to claim 1, wherein each of the plurality of insulating regions with different surface energy densities is structured.

3. The organic film according to claim 1, wherein a difference between a surface energy density of an insulating region of the plurality of insulating regions with different surface energy densities and a surface energy density of another insulating region adjacent to the insulation region is 10 dyne/cm or more.

4. The organic film according to claim 1, wherein each of the plurality of insulating regions with different surface energy densities is structured with a period of 1 μm or less.

5. The organic film according to claim 1, wherein each of the plurality of insulating regions with different surface energy densities is structured with a period of a 0.5 times or more and 100 times or less molecular length of a compound constituting the organic film.

6. The organic film according to claim 1, wherein a difference in height between an insulating region of the plurality of insulating regions with different surface energy densities and another insulating region adjacent to the insulating region is 0.5 nm or more and 100 nm or less.

7. The organic film according to claim 1, wherein the compound constituting the organic film has electrical conductivity.

8. The organic film according to claim 0.1, wherein the compound constituting the organic film is a polymer compound.

9. The organic film according to claim 1, wherein the compound constituting the organic film exhibits liquid crystallinity.

10. A method of producing the organic film according to claim 1, comprising forming a plurality of insulating regions with different surface energy densities by using an electron beam or near field light.

11. A field effect transistor comprising the organic film according to claim 1 for a channel part of the field effect transistor.
